(19) United States
(12) Patent Application Publication
(10) Pub. No.: US 2009/0001416 A1
(43) Pub. Date: Jan. 1, 2009

(54) Growth of indium gallium nitride (InGaN) on porous gallium nitride (GaN) template by metal-organic chemical vapor deposition (MOCVD)

(75) Inventors: Soo Jin Chua, Singapore (SG); Haryono Hartono, Singapore (SG); Chew Beng Soh, Singapore (SG)

Correspondence Address: SAILE ACKERMAN LLC, 28 DAVIS AVENUE, POUGHKEEPSIE, NY, 12603, US

(73) Assignee: National University of Singapore

(21) Appl. No.: 11/823,756

(22) Filed: Jun. 28, 2007

(51) Int. Cl. H01L 29/205; H01L 21/20

(52) U.S. Cl. 257/190; 438/504; 257/E21.09; 257/E29.091

(57) ABSTRACT

Si-doped porous GaN is fabricated by UV-enhanced Pt-assisted electrochemical etching and together with a low-temperature grown buffer layer are utilized as the template for InGaN growth. The porous network in GaN shows nanostructures formed on the surface. Subsequent growth of InGaN shows that it is relaxed on these nanostructures as the area on which the growth takes place is very small. The strain relaxation favors higher indium incorporation. Besides, this porous network creates a relatively rough surface of GaN to modify the surface energy which can enhance the nucleation of impinging indium atoms thereby increasing indium incorporation. It shifts the luminescence from 445 nm for a conventionally grown InGaN structure to 575 nm and enhances the intensity by more than two-fold for the growth technique in the present invention under the same growth conditions. There is also a spectral broadening of the output extending from 480 nm to 720 nm.

### FIELD OF THE INVENTION

This invention relates to optoelectronics devices and fabrication methods, particularly to light emitting diodes (LEDs) and laser diodes (LDs).

### BACKGROUND OF THE INVENTION

Light emitting diodes are widely used in optical displays, traffic lights, data storage, communications, medical and many other applications.

Recent breakthroughs in blue emitting GaN-based LEDs and LDs have attracted much attention on the growth of group III-nitrides, in particular InGaN. InGaN is a very important material because it is used as the active layer of LEDs and LDs. The band gap of InGaN can be varied to provide light over nearly the whole spectral range from near UV to red from the combination of GaN and InN band gap. However, there are problems impeding the progress in the growth of indium-rich InGaN, which include poor optical properties, low percentage of indium incorporation, phase separation, and the formation of indium droplets on the surface. For growing InGaN, the most widely used substrate to date has been sapphire, which (0001) plane is normally used. It has a mismatch as large as 22% for InN, 14% for GaN and 12% for AlN.

The growth of InGaN alloys is very challenging, mostly due to the trade off between the epilayer quality and the amount of indium incorporated into the alloy as the growth temperature is changed. Difficulties in the metal organic chemical vapor deposition (MOCVD) growth of high quality InGaN arise mainly because the InN decomposes at a low temperature of around 500° C. while below 1000° C., the decomposition of ammonia is low. The indium incorporation in InGaN films was found to be enhanced with decreasing growth temperatures varying from 850° C. to 500° C. Growth at a high temperature of about 800° C. typically results in high crystalline quality but with a low amount of indium incorporation because of the high volatility of nitrogen N over InN [T. Matsuoka, N. Yoshimoto, T. Sasaki, and A. Katsui, J. Electron. Mater. 21, 157 (1992)]. Attempts to increase the indium incorporation in the solid by raising the indium pressure in the vapor result in indium droplet formation [M. Shimizu, K. Hiramatsu, and N. Sawaki, J. Cryst. Growth 145, 209 (1994)]. There is also strong evidence of phase separation in thick InGaN films grown by both molecular beam epitaxy (MBE) and MOCVD [N. A. El-Masry, E. L. Piner, S. X. Liu, and S. M. Bedair, Appl. Phys. Lett. 72, 40 (1998)]. Behbehani et al. reported the occurrence of phase separation and ordering in InGaN with indium percentage of more than 25% [M. K. Behbehani, E. L. Piner, S. X. Liu, N. A. El-Masry, and S. M. Bedair, Appl. Phys. Lett. 75, 2202 (1999)]. All these difficulties arise because of the large difference in inter-atomic spacing between GaN and InN which gives rise to a solid phase miscibility gap and limits the equilibrium InN mole fraction in GaN at a particular growth temperature [I. Ho and G. B. Stringfellow, Appl. Phys. Lett. 69, 2701 (1996)].

Beside the problems that arise from the solid phase miscibility gap between GaN and InN, there is still another problem that arises because of the lack of suitable substrates for GaN and its alloy. GaN layers are mainly prepared by heteroepitaxy on foreign substrates, such as sapphire, silicon and SiC [Y. D. Wang, K. Y. Zang, S. J. Chua, S. Tripathy, P. Chen, and C. G. Fonstad, Appl. Phys. Lett. 87, 251915 (2005)]. Such heteroepitaxy growth typically gives rise to high dislocation density and residual strain as the result of lattice mismatch and thermal expansion coefficient difference, which are detrimental to the electrical and optical properties of GaN-based devices. Many ways have been investigated to reduce the effects of this problem, though, to date there are still many defects in the epilayer. An alternate way to achieve a high-quality strain-released GaN epilayer is by realizing a selective and lateral growth on a patterned substrate, which has been known to improve film quality [O. H. Nam, M. D. Bremser, T. S. Zheleva, and R. F. Davis, Appl. Phys. Lett. 71, 2638 (1997); A. Sakai, H. Sunakawa, and A. Usui, Appl. Phys. Lett. 71, 2259 (1997); T. M. Katona, J. S. Speck, and S. P. Denbaars, Appl. Phys. Lett. 81, 3558 (2002)]. Mynbaeva et al. reported that the growth of GaN on porous GaN can lead to high-quality strain-released epilayers [M. Mynbaeva, A. Titkov, A. Kryganovskii, V. Ranikov, K. Mynbaev, H. Huhtinen, R. Laiho, and V. Dmitriev, Appl. Phys. Lett. 76, 1113 (2000)].

Usui et al. (U.S. Pat. No. 6,812,051) reported a method of forming an epitaxially grown nitride-based compound semiconductor crystal substrate structure with a reduced dislocation density using a porous template. The porous structure was formed by depositing a metal layer which was selected in connection with the GaN base layer, such that a nitride of the selected metal has a lower free energy than the free energy of the nitride in the base layer. This promotes removal of nitrogen atoms from the GaN base layer, hence creating many pores in the metal layer and voids in the GaN base layer with the assistance of a heat treatment. It is claimed that the upper region or the surface region of the epitaxially grown nitride-based compound semiconductor crystal layer over the porous metal nitride has a much lower dislocation density on average than the nitride-based compound semiconductor base layer.

Sakaguchi et al. (U.S. Pat. No. 6,972,215) reported a semiconductor device manufactured using the method including the steps of anodizing a semiconductor substrate to form a porous semiconductor layer (100) on a semiconductor region of the semiconductor substrate (130); forming a non-porous semiconductor layer (110) on the porous semiconductor layer; forming a semiconductor element and/or semiconductor integrated circuit in the non-porous semiconductor layer. The porous semiconductor layer is a porous silicon layer formed by anodizing the surface of a single-crystal silicon wafer or an ion-implanted layer formed by implanting hydrogen ions, helium ions, or rare gas ions to a desired depth of a single-crystal silicon wafer. After annealing, a non-porous thin film such as a single-crystal Si, GaAs, InP, or GaN film is grown on the porous silicon layer by CVD or the like.

Fukunaga et al. (U.S. Pat. No. 6,709,513) reported a process for producing a substrate with a wide low-defect region for use in semiconductor applications. A porous anodic alumina film having a great number of minute pores is formed on a surface of a base substrate. The surface of the base substrate is then etched by using the porous anodic alumina film as a mask so as to form a great number of pits on the surface of the base substrate. Upon removal of the porous anodic alumina film a GaN layer is grown on the surface of the base substrate by crystal growth.

Although all the methods described above utilize a porous template to grow a film or epilayer with reduced dislocation density, none has an objective to achieve high indium incorporation in InGaN. In addition to that, the porous fabrication method described in the present invention is simpler and more cost-effective as it eliminates some steps for layer depositions and/or anodizing process.

### SUMMARY OF THE INVENTION

It is an object of the present invention to provide a technique to significantly increase indium incorporation and achieve a significant red-shift in the wavelength emission of InGaN.

It is a further object of the present invention to increase indium incorporation and achieve a significant red-shift in the wavelength emission of InGaN by using a porous GaN template for the growth of the buffer layer and InGaN epilayer.

A still further object of the invention is to provide a porous GaN template for growth of the buffer layer and InGaN epilayer by using photoelectrochemical (PEC) etching.

In accordance with the objects of the invention, a method is provided comprising the use of porous GaN to achieve high incorporation of indium in a InGaN epilayer. A substrate is provided comprising a porous surface layer of a group III-nitride, maintaining the substrate at a temperature in the range of 550° C. to 900° C. for a duration of 1 to 60 minutes for cleaning and annealing processes before any further growths on the porous surface layer. While maintaining the substrate at a temperature in the range of 650° C. to 900° C., a buffer layer is formed over the porous surface layer. While maintaining the substrate at a temperature in the range of 700° C. to 800° C., a layer of InₓGa₁₋ₓN is formed over the buffer layer wherein x ranges from 0.01 to 0.5. While maintaining the substrate at about the temperature of the previous step, a cap layer of GaN is formed over the InₓGa₁₋ₓN layer; thereby achieving a significant red-shift in the wavelength emission of InGaN.

Also in accordance with the objects of the invention, an InGaN epilayer having a high incorporation of indium is achieved. The InGaN epilayer comprises: a porous surface layer of a group III-nitride on a substrate wherein the porous surface layer has a roughened surface, a buffer layer over the porous surface layer wherein the buffer layer also has a roughened surface, a layer of InₓGa₁₋ₓN over the buffer layer wherein x ranges from 0.01 to 0.5, and a cap layer of GaN over the InₓGa₁₋ₓN layer, wherein the wavelength emission of the InGaN epilayer is in the range from 480 nm to 720 nm.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 5 illustrate in cross-sectional representation the growth of the InGaN layer in a preferred embodiment of the present invention.

FIG. 6 graphically illustrates room temperature photoluminescence from the InGaN layer formed in a conventional method and the InGaN layer formed in the process of the present invention.

FIG. 7 is a scanning electron microscope (SEM) photograph showing the surface morphology of the as-fabricated porous GaN of the present invention.

FIG. 8 is the cross-section transmission electron microscopy (TEM) image of the as-fabricated porous GaN of the present invention.

It is to be noted that the drawings of the invention are not to scale. In the drawings, the thicknesses of layers and regions are exaggerated for clarity. The drawings are intended to depict only typical aspects of the invention and therefore should not be considered as limiting the scope of the invention.

### DETAILED DESCRIPTION OF THE INVENTION

The conventional method of InGaN growth is as follows: first, a low-temperature nucleation layer is grown, followed by growth of a high-temperature GaN layer, with the former usually performed in the range of 450° C. to 600° C., and the latter usually performed in the range of 900° C. to 1100° C., most typically at about 1015° C. to 1030° C. The temperature is next lowered to about 700° C. to 800° C. to grow the InGaN layer.

According to the invention, it has been found that the main-peak of room temperature photoluminescence from the InₓGa₁₋ₓN layer is 575 nm with a spectral broadening extending from 480 nm to 720 nm. It shows a significant red-shift and enhancement of intensity as compared to the emission of a InₓGa₁₋ₓN layer grown by the conventional method with the same growth conditions (including TMIn and TMGa flows, growth temperature, and pressure).

The porous GaN layer of the present invention acting as the growth template is very important for the quality of layer subsequently grown and the incorporation of indium in InGaN layer. The porous network results in GaN nanostructures being formed on the surface on which an InGaN layer is subsequently grown. It results in strain relaxation as the area on which the growth takes place is very small. The strain relaxation favors higher indium incorporation. There are several factors affecting the porous morphology: the current applied, the etching duration, and the concentration of the electrolyte. If any of the three factors is too low, high density uniform pores on the surface will not be formed. On the contrary, if any of the three factors is too high, the porous surface will peel-off and the pore size will get too big.

The growth temperature of the low temperature GaN layer acting as the buffer layer of the porous template is also important for the quality of layer subsequently grown and the incorporation of indium in the InGaN layer. If the temperature is too low the quality of the subsequent layer grown will be degraded, and on the contrary, if the temperature is too high the rough surface will be smoothened. This rough surface modifies the surface energy which helps the impinging indium atoms coming from the cracking of the TMIn precursor to nucleate. So the smoothening of the surface will result in the lowering of the indium incorporation.

The present invention is now described more fully hereinafter with reference to the accompanying drawings. This invention may, however, be embodied in many different forms and should not be construed as limited to the embodiments set forth herein. Rather, the invention is defined by the following claims.

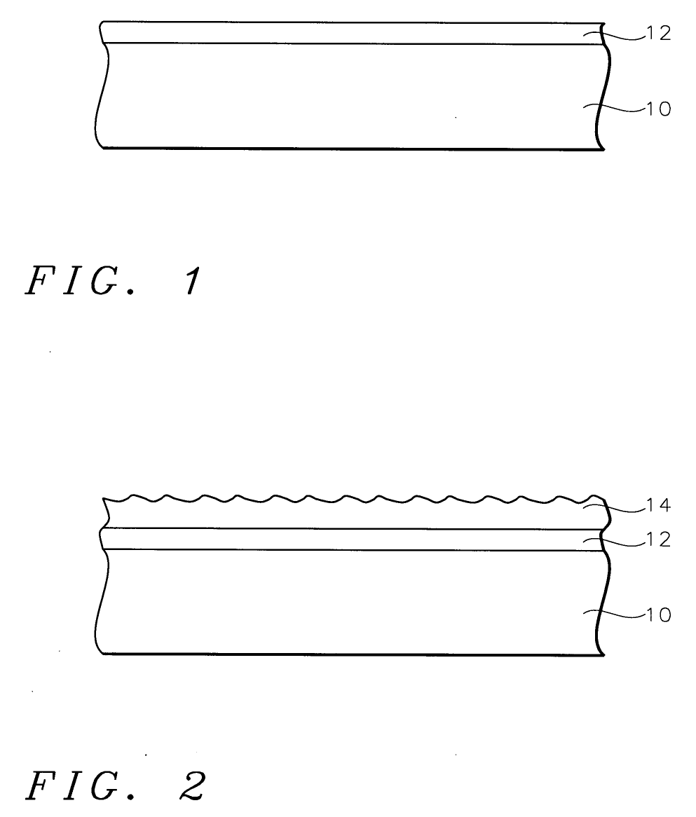

FIGS. 1 through 5 illustrate steps in the present invention fabrication of the InGaN structure which can be used to achieve InGaN emission with significant red-shift. Referring now to FIG. 1, there is shown substrate 10 which can be sapphire, silicon, silicon carbide (SiC), zinc oxide (ZnO) or other suitable substrates. The substrate may have a thickness of between about 200 and 500 μm. In a preferred embodiment of the present invention, the substrate is a (0001) sapphire substrate. First, a low-temperature GaN nucleation layer 12 is grown on the substrate 10. Growth is by MOCVD. Trimethylgallium (TMGa) and ammonia (NH₃) are the Ga and N precursors, respectively; and hydrogen (H₂) and/or nitrogen (N₂) are the carrier gases. Alternatively, triethylgallium (TEGa) or ethyldimethylgallium (EDMGa) could also be used as group III precursors, while dimethylhydrazine (H₂N₂(CH₃)₂, 1, 1 DMHy) is preferred as the N precursor. The GaN nucleation layer 12 is grown at a temperature of between about 450° C. to 600° C., and preferably about 520° C. to a thickness of between about 20 and 40 nm, and preferably about 35 nm thick. Alternatively, the nucleation layer 12 can be AlN or a multi-layered AlGaN/GaN buffer. Also, alternatively, growth may be by molecular beam epitaxy (MBE).

Referring to FIG. 2, a porous Si-doped GaN layer 14 is now formed. Growth of layer 14 is by MOCVD or MBE. The porous GaN layer is formed at a temperature of between about 900° C. to 1100° C. and preferably, about 1015° C. to 1030° C. The doping concentration ranges from 1×10¹⁷ to 9×10¹⁸ cm⁻³,and preferably 8×10¹⁷ to 5×10¹⁸ cm⁻³, as determined by Hall measurement. Instead of silicon-doped GaN, any other n-doped GaN can be used. In the present invention, the GaN layer 14 is made porous by subjecting it to photoelectrochemical (PEC) etching. PEC etching includes two primary components: a light source, which is a UV light, and an electrochemical cell. The electrochemical cell is basically an electrical circuit between the semiconductor—GaN in the present invention—and the Pt electrode with an electrolyte serving as the conductive medium. When the UV illuminates the sample, electron/hole pairs are created, without which the equilibrium density of holes in n-type GaN in the dark is too low for a significant etching to take place. A signature of PEC etching in most semiconductors is the dramatically higher rate of etching of n-type materials over semi-insulating or p-type materials [R. Khare, D. B. Young, G. L. Snider, and E. L. Hu, Appl. Phys. Lett. 62, 1809 (1993)]. This is a consequence of the band bending at the material—electrolyte interface, and the efficacy of hole confinement. In the fabrication of porous GaN used in this invention, UV-enhanced Pt-assisted electrochemical etching is performed for a duration varying from 30 to 60 minutes under annodization current density of 5 mA/cm² to 25 mA/cm² in a dilute alkaline solution or a dilute acid solution. This layer is between about 1 and 4 μm thick, and preferably about 1.8 μm thick. The use of the porous GaN template for this embodiment is important to shift the luminescence spectrum of InGaN from 445 nm for a conventionally grown structure to 575 nm for the growth technique in the present invention.

After the fabrication of the porous GaN layer 14, a low temperature buffer layer 16 is grown by MOCVD or MBE, as shown in FIG. 3. Prior to this growth, cleaning and annealing of the surface porous layer is done inside the growth chamber at a temperature ranging from 550° C. to 900° C. for a duration of 1 to 60 minutes, and preferably about 2 to 10 minutes. Subsequently, a GaN buffer layer 16 is grown at a temperature in the range from 650° C. to 900° C. to a thickness of between about 10 to 200 nm, and preferably about 100 nm thick. AlN could also be used instead of GaN. The insertion of layer 16 is important for the quality of the layer to be subsequently grown and the incorporation of indium in the InGaN layer. The growth of layer 16 must maintain the rough surface of the porous template, as shown in the figures, and yet still be suitable for growing a high quality InGaN layer. The rough surface is to modify the surface energy which can enhance the nucleation of impinging indium atoms, obtained from the cracking of TMIn, thereby increasing the indium incorporation in the InGaN layer in 18, shown in FIG. 4. It is also thought that a low temperature GaN layer as in layer 16 partially relaxes the compressive strain between the InGaN and GaN layers. This strain relaxation can result in a red shift in the luminescence.

Next, as illustrated in FIG. 4, an InₓGa₁₋ₓN layer is grown on the buffer layer 16, wherein x ranges from 0.01 to 0.5. This InGaN layer 18 is grown at a temperature in the range of 700° C. to 800° C. and to a thickness of between about 5 to 120 nm. Trimethylindium (TMIn), triethylindium (TEIn), or ethyldimethylindium (EDMIn) can be used as the precursor for In. Growth is by MOCVD. Trimethylgallium (TMGa) and ammonia (NH₃) are the Ga and N precursors, respectively; and hydrogen (H₂) and/or nitrogen (N₂) are the carrier gases. Alternatively, triethylgallium (TEGa) or ethyldimethylgallium (EDMGa) could also be used as group III precursors, while dimethylhydrazine (H₂N₂(CH₃)₂, 1, 1 DMHy) is preferred as the N precursor. Alternatively, this layer could be InGaN quantum well (QW) or InGaN multi quantum well (MQW) instead of a single layer InGaN.

Finally, as illustrated in FIG. 5, layer 20 is the GaN cap grown at the same temperature as that of layer 18. The thickness of the GaN cap layer is between about 10 nm to 1000 nm.

FIG. 5 illustrates the completed InGaN structure comprising a low temperature nucleation layer formed on a substrate and a porous GaN layer formed on the nucleation layer, wherein the surface of the porous layer is roughened. A low temperature buffer layer on the porous layer maintains the surface roughness of the layer. An InGaN layer with high incorporation of indium atoms overlies the porous layer. Finally, a GaN cap completes the stack. The InGaN structure of the present invention allows a shift in the luminescence spectrum of InₓGa₁₋ₓN from 445 nm for a conventionally grown structure to 575 nm for the growth technique in the present invention under the same growth conditions (including TMIn and TMGa flows, growth temperature, and pressure).

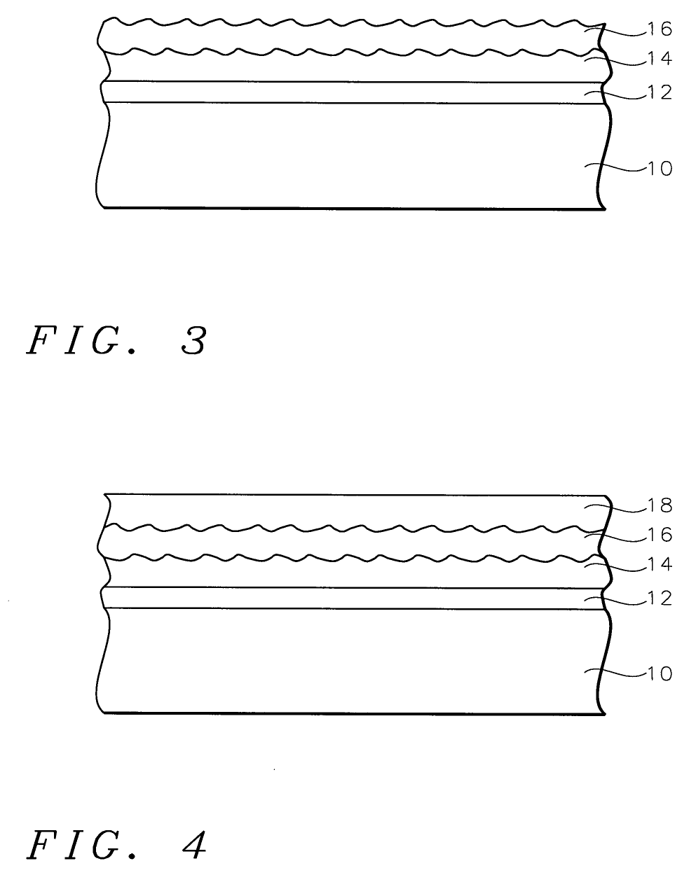

FIG. 6 shows the room temperature photoluminescence from the InₓGa₁₋ₓN layer of the embodiment, shown in solid line 61 with the wavelength emission in the range from 480 nm to 720 nm with the main peak emission at 575 nm. It also shows the photoluminescence from a conventionally grown InₓGa₁₋ₓN structure for comparison, with the emission at 445 nm, shown as a dashed line 62. The thicknesses and growth conditions of the InₓGa₁₋ₓN layers are the same for both samples. There is a significant increase of the indium incorporation as shown by the red-shift of as much as 130 nm in the wavelength emission of InₓGa₁₋ₓN grown at the present invention as compared to the conventional method.

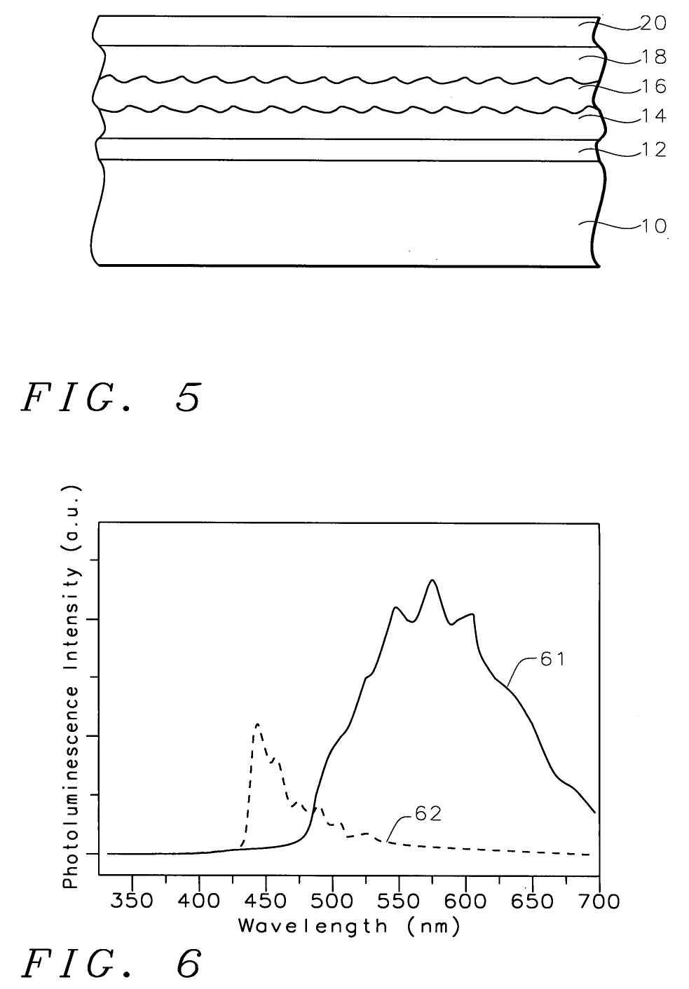

FIG. 7 shows the SEM picture of the surface morphology of the as-fabricated porous GaN layer 14. The lateral size of the pores varies from 20 nm to 200 nm.

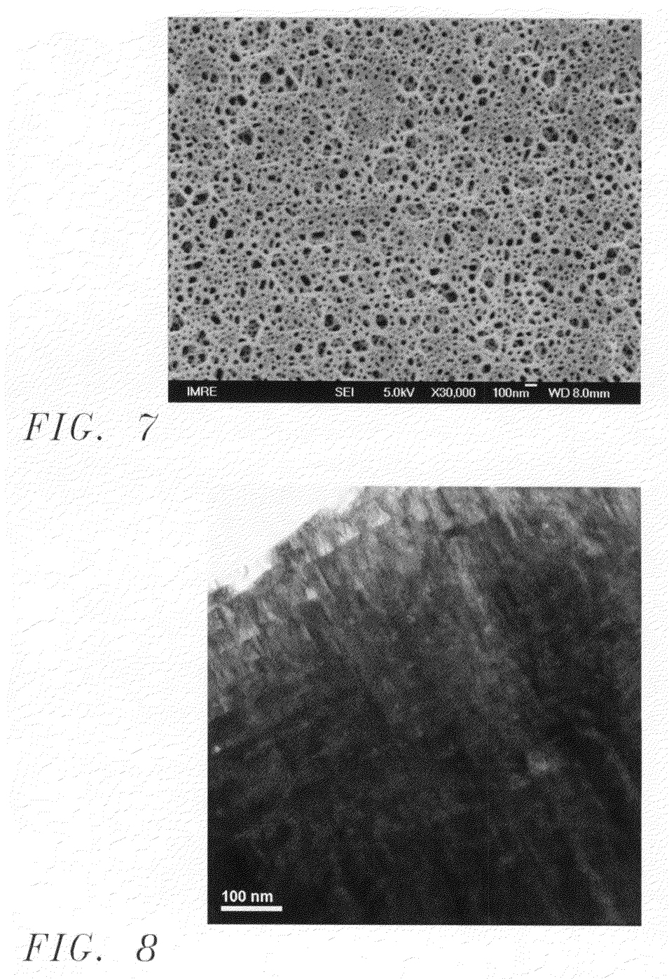

FIG. 8 shows the cross-section transmission electron microscopy (TEM) of the as-fabricated porous GaN layer 14. The pores were formed along the (0001) direction towards the sapphire substrate 10.

Various articles in scientific periodicals are cited throughout this application. Each of such articles is hereby incorporated by reference in its entirety and for all purposes by such citation.

What is claimed is:

1. The use of porous GaN to achieve high incorporation of indium in a InGaN epilayer, comprising:
i) providing a substrate comprising a porous surface layer of a group III-nitride, maintaining said substrate at a temperature in the range of 550° C. to 900° C. for a duration of 1 to 60 minutes for cleaning and annealing processes;
ii) maintaining said substrate at a temperature in the range of 650° C. to 900° C., while forming a buffer layer over said porous surface layer;
iii) maintaining said substrate at a temperature in the range of 700° C. to 800° C., while forming a layer of InₓGa₁₋ₓN over said buffer layer wherein x ranges from 0.01 to 0.5; and
iv) maintaining said substrate at about the temperature of step iii) while forming a cap layer of GaN over said InₓGa₁₋ₓN layer; thereby achieving a significant red-shift in the wavelength emission of InGaN.

2. The method of claim 1, wherein said group III-nitride is GaN.

3. The method of claim 2, wherein said GaN is n-doped with a doping concentration ranging from 1×10¹⁷ to 9×10¹⁸ cm⁻³.

4. The method of claim 1, wherein said porous surface layer is created by photoelectrochemical etching comprising an annodization current density of 5 mA/cm² to 25 mA/cm² supplied for 30 to 60 minutes in dilute alkaline or acid solution.

5. The method of claim 1, wherein said buffer layer comprises GaN.

6. The method of claim 1, wherein said forming steps ii, iii, and iv are performed by metal organic chemical vapor deposition using trimethylgallium, triethylgallium, ethyldimethylgallium, or a mixture of at least two thereof as a gallium precursor.

7. The method of claim 1, wherein said forming step iii is performed by metal organic chemical vapor deposition wherein trimethylindium, triethylindium, ethyldimethylindium, or a mixture of at least two thereof is used as an indium precursor.

8. The method of claim 6, wherein ammonia or dimethylhydrazine is used as a nitrogen precursor and hydrogen, nitrogen, or a mixture thereof is used as a carrier gas.

9. The method of claim 1, wherein said forming steps ii, iii, and iv are performed by molecular beam epitaxy (MBE).

10. The method of claim 1, wherein the wavelength emission of said InGaN epilayer is in the range from 480 nm to 720 nm.

11. A method of fabricating an InGaN epilayer having a high incorporation of indium, comprising:
i) providing a nucleation layer on a substrate;
ii) providing a porous surface layer of a group III-nitride over said nucleation layer wherein said porous surface layer has a roughened surface, maintaining said substrate at a temperature in the range of 550° C. to 900° C. for a duration of 1 to 60 minutes for cleaning and annealing processes;
iii) while maintaining said substrate at a temperature in the range of 650° C. to 900° C., forming a buffer layer over said porous surface layer wherein said buffer layer also has a roughened surface;
iv) while maintaining said substrate at a temperature in the range of 700° C. to 800° C., forming a layer of InₓGa₁₋ₓN over said buffer layer wherein x ranges from 0.01 to 0.5; and
v) while maintaining said substrate at about the temperature of step iv), forming a cap layer of GaN over said InₓGa₁₋ₓN layer; thereby achieving a significant red-shift in the wavelength emission of InGaN.

12. The method of claim 11, wherein said nucleation layer and said buffer layer comprise GaN or AlN.

13. The method of claim 11, wherein said group III-nitride is an n-doped GaN.

14. The method of claim 11, wherein said porous surface layer is created by photoelectrochemical etching comprising an annodization current density of 5 mA/cm² to 25 mA/cm² supplied for 30 to 60 minutes in dilute alkaline or acid solution.

15. The method of claim 11, wherein said forming steps ii-iv are performed by metal organic chemical vapor deposition using trimethylgallium, triethylgallium, ethyldimethylgallium, or a mixture of at least two thereof as a gallium precursor and wherein ammonia or dimethylhydrazine is used as a nitrogen precursor and hydrogen, nitrogen, or a mixture thereof is used as a carrier gas.

16. The method of claim 11, wherein said forming step iv is performed by metal organic chemical vapor deposition wherein trimethylindium, triethylindium, ethyldimethylindium, or a mixture of at least two thereof is used as an indium precursor.

17. The method of claim 11, wherein said forming steps ii-v are performed by molecular beam epitaxy (MBE).

18. The method of claim 11, wherein the wavelength emission of said InGaN epilayer is in the range from 480 nm to 720 nm.

19. An InGaN epilayer having a high incorporation of indium, comprising:
a porous surface layer of a group III-nitride on a substrate wherein said porous surface layer has a roughened surface;
a buffer layer over said porous surface layer wherein said buffer layer also has a roughened surface;
a layer of InₓGa₁₋ₓN over said buffer layer wherein x ranges from 0.01 to 0.5; and
a cap layer of GaN over said InₓGa₁₋ₓN layer, wherein the wavelength emission of said InGaN epilayer is in the range from 480 nm to 720 nm.
